(19) United States
(12) Patent Application Publication
(10) Pub. No.: US 2008/0096137 A1
(43) Pub. Date: Apr. 24, 2008

(54) METHOD FOR FABRICATING FLOW CHANNEL CAPABLE OF BALANCING AIR PRESSURE

(76) Inventor: Hong-Da Chang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/762,766

(22) Filed: Jun. 13, 2007

(30) Foreign Application Priority Data
Oct. 23, 2006 (TW) 095139015

(51) Int. Cl. H01L 23/58

(52) U.S. Cl. 430/313; 29/829; 430/320

(57) ABSTRACT

A method for fabricating flow channel capable of balancing air pressure. A device wafer is provided, and a plurality of chambers not conducting to each other are formed on the front surface of the device wafer. Subsequently, a plurality of flow channels are formed on the front surface of the device wafer, and the chambers are conducting to each other by virtue of the flow channels. The front surface of the device wafer is then adhered to a carrier wafer. The pressure inside the chambers and that outside the chambers is therefore balanced.

### BACKGROUND OF THE INVENTION

1. Field of the Invention

The present invention relates to a method of fabricating flow channels capable of balancing air pressure, and more particularly, to a method able to prevent the wafer form being damaged during double side process due to pressure differences.

2. Description of the Prior Art

Compared to the structure of semiconductor devices, the structure of MEMS devices is normally more complicated because they have both electronic and mechanical features. Accordingly, the MEMS devices require double side process to be fabricated. In current MEMS device fabrications, such as in micro sensor, micro actuator and micro mirror structure processes, chambers must be formed on the front surface of the wafer by a front surface process. The front surface of the wafer having chambers thereon is then adhered to a carrier wafer, and a back surface process is performed upon the wafer. However, when the front surface of the wafer is bonded to the carrier wafer, the chambers disposed on the front surface of the wafer will be sealed by the carrier wafer and a bonding layer, thereby forming sealed spaces. In addition, current processes are generally performed under vacuum condition. Under such a condition, the structure of MEMS device is liable to break in the back surface process due to the pressure differences between the inner space of the chambers and the environment. This problem gets more serious when a thin wafer is used.

### SUMMARY OF THE INVENTION

It is therefore one of the objectives of the claimed invention to provide a method of fabricating flow channels capable of balancing air pressure to improve the yield of double side process.

According an embodiment of the present invention, a method of fabricating flow channels capable of balancing air pressure is provided. The method includes the following steps:

providing a device wafer comprising a front surface;

performing a front surface process upon the device wafer, the front surface process comprising forming a plurality of chambers not conducting to each other on the front surface of the device wafer;

forming a plurality of flow channels on the front surface of the device wafer, the chambers being conducting to each other by virtue of the flow channels; and

providing a carrier wafer, and adhering the front surface of the device wafer to the carrier wafer, wherein the carrier wafer is disposed over the chambers of the device wafer, and the pressure inside the chambers and the pressure outside the chambers are balanced by virtue of the flow channels.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 are schematic diagrams illustrating a method of fabricating flow channels capable of balancing air pressure according to a preferred embodiment of the present invention.

FIGS. 6-11 are schematic diagrams illustrating a method of fabricating flow channels capable of balancing air pressure according to another embodiment of the present invention.

### DETAILED DESCRIPTION

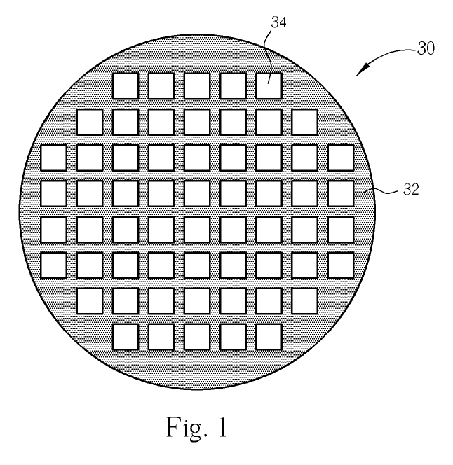

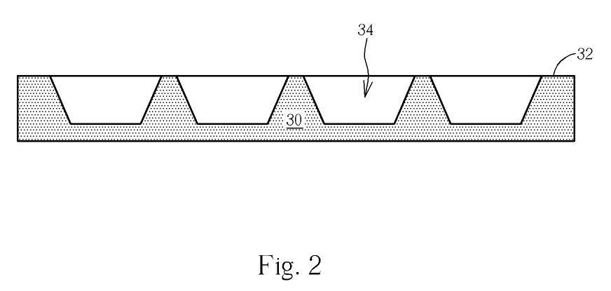

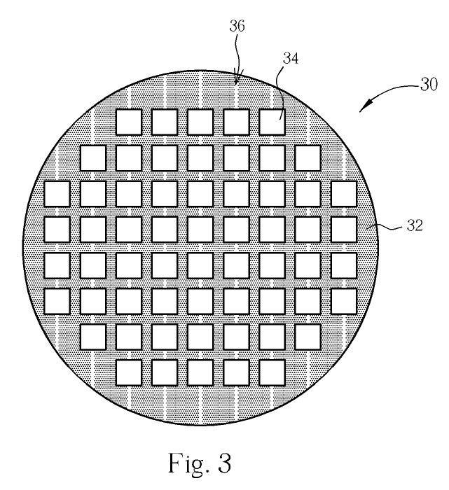

Please refer to FIGS. 1-5. FIGS. 1-5 are schematic diagrams illustrating a method of fabricating flow channels capable of balancing air pressure according to a preferred embodiment of the present invention, where FIGS. 1 and 3 are top views, and FIGS. 2, 4 and 5 are cross-sectional views. As shown in FIGS. 1-2, a device wafer 30 e.g. a silicon wafer is provided. The device wafer 30 has a front surface 32. Subsequently, a front surface process is performed upon the front surface 32 of the device wafer 30. The front surface process can be various semiconductor or MEMS processes, such as deposition, photolithography, etching and implantation processes wherever necessary. In this embodiment, the front surface process includes forming a plurality of chambers 34 on the front surface 32 of the device wafer 30. The chambers 34 may be formed by either a dry etching processes such as reactive ion etching or a wet etching process which uses an etching solution e.g. potassium hydroxide (KOH) solution or Tetramethylammonium hydroxide (TMAH) solution. It is appreciated that the chambers 34 are not conducting to each other after the etching process.

As shown in FIG. 3, a cutting process is performed using a cutter to form a plurality of flow channels 36 on the front surface 32 of the device wafer 30. The function of the flow channels 36 is to conduct the chambers 34 without influencing the structures of the chambers 34, and thus the depth of the flow channels 36 is smaller than the depth of the chambers 34. In this embodiment, the flow channels 36 are arranged longitudinally and in stripes, but not limited. The flow channels 36 can be arranged in other ways such as latitudinally, diagonally, or in matrix as long as the chambers 34 can conduct to the environment there through.

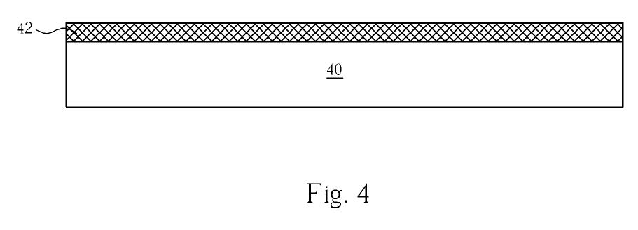

As shown in FIG. 4, a carrier wafer 40 is provided, and a bonding layer 42 is formed on the surface of the carrier wafer 40. The material of the bonding layer can be photoresist, benzocyclobutene (BCB), polyimide, wax, dry film, thermal release tape, UV tape, or any other suitable materials that can be removed subsequently by etching, heating, irradiating, etc.

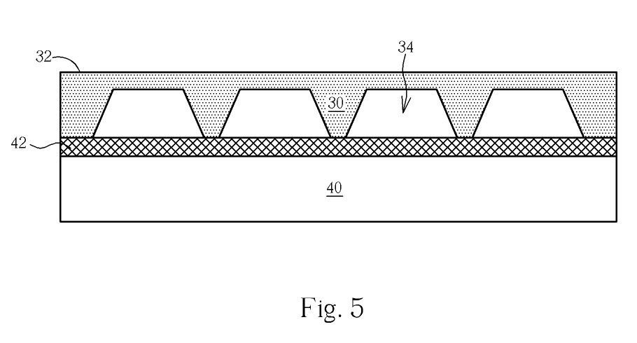

As shown in FIG. 5, the front surface 32 of the device wafer 30 is adhered to the carrier wafer 40 with the bonding layer 42, and a back surface process is performed upon the device wafer 30. The bonding layer 42 is then removed to separate the carrier wafer 40 from the device wafer 30. By virtue of the flow channels 36, the chambers 34 are not sealed by the bonding layer 42 and the carrier wafer 40 in the back surface process so that the chambers 34 can conduct to the environment. The flow channels 36 keep the pressure inside the chambers 34 and the pressure outside the chambers 34 equal so that the structures of MEMS devices are not damaged in the back surface process.

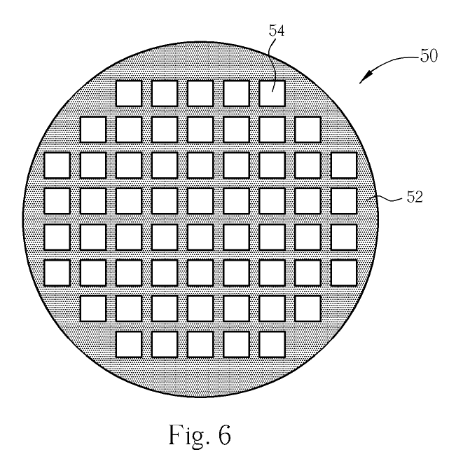

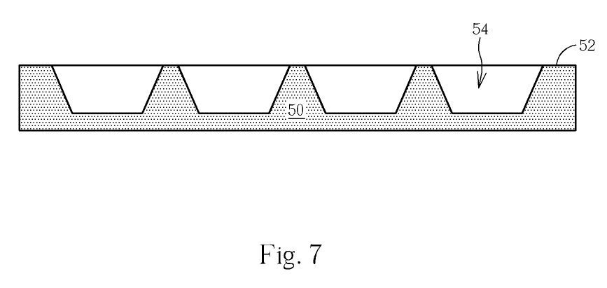

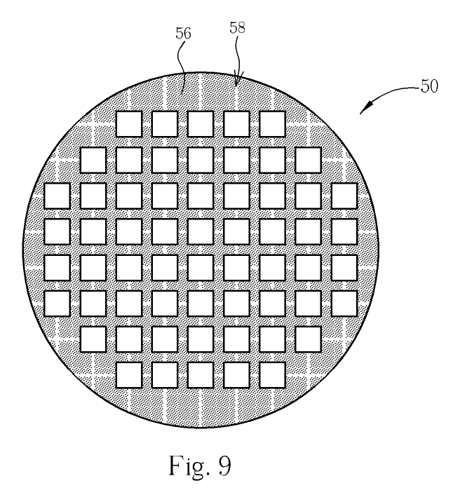

Please refer to FIGS. 6-11. FIGS. 6-11 are schematic diagrams illustrating a method of fabricating flow channels capable of balancing air pressure according to another embodiment of the present invention, where FIGS. 6 and 9 are top views, and FIGS. 7, 8, 10 and 11 are cross-sectional views. As shown in FIGS. 6-7, a device wafer 50 is provided. The device wafer 50 has a front surface 52. Subsequently, a front surface process is performed upon the front surface 52 of the device wafer 50. The front surface process includes forming a plurality of chambers 54, which do not conduct to each other, on the front surface 52 of the device wafer 50.

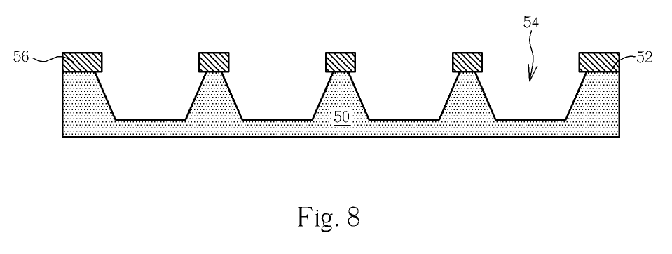

As shown in FIGS. 8-9, a sacrificial layer 56 is formed on the front surface 52 of the device wafer 50. The sacrificial layer 56 can be a photosensitive sacrificial layer, which can be partially removed by a photolithography process to form a plurality of flow channels 58. The sacrificial layer 54 can also be non-photosensitive. In such a case, a photoresist layer (not shown) is required to dispose on the sacrificial layer 56, and photolithography and etching techniques must be used to define the flow channels 58. The flow channels 58 are formed to make the chambers 54 conduct to each other. In this embodiment, the flow channels 58 are arranged in matrix but not limited. The flow channels 58 may also be arranged in other ways such as longitudinally, latitudinally or diagonally in stripes.

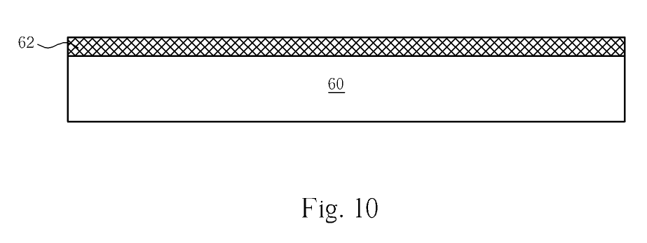

As shown in FIG. 10, a carrier wafer 60 is provided, and a bonding layer 62 is formed on the surface of the carrier wafer 60. The material of the bonding layer 62 can be any adhesive materials that may be removed by etching, heating, irradiating, or other ways without damaging the device wafer 50.

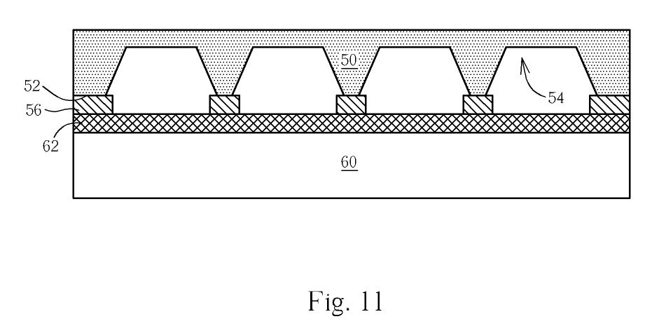

As shown in FIG. 11, the front surface 52 of the device wafer 50 is adhered to the carrier wafer 60 with the bonding layer 62, and a back surface process is performed upon the device wafer 50. The bonding layer 62 is removed subsequent to the back surface process to separate the carrier wafer 60 from the device wafer 50. By virtue of the flow channels 58, the chambers 54 are not sealed by the bonding layer 62 and the carrier wafer 60 in the back surface process so that the chambers 54 can lead to the environment. The flow channels 58 keep the pressure inside the chambers 54 and the pressure outside the chambers 54 equal so that the structures of MEMS devices are not damaged in the back surface process.

The method of the present invention forms the flow channels able to release the air pressure inside the chambers, and therefore the structures of MEMS devices will not be damaged due to pressure difference in the back surface process. Consequently, the method of the present invention can improve the yield of double side process, and particularly for the double side process which uses a thin wafer of a thickness less than 200 micrometers. In addition, the method of the present invention used a carrier wafer to support the device wafer. The carrier wafer is compatible with current wafer delivery configurations, and therefore the delivery configurations do not have to be redesigned.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a flow channel capable of balancing air pressure, comprising:
providing a device wafer comprising a front surface;
performing a front surface process upon the device wafer, the front surface process comprising forming a plurality of chambers not conducting to each other on the front surface of the device wafer;
forming a plurality of flow channels on the front surface of the device wafer, the chambers being conducting to each other by virtue of the flow channels; and
providing a carrier wafer, and adhering the front surface of the device wafer to the carrier wafer, wherein the carrier wafer is disposed over the chambers of the device wafer, and the pressure inside the chambers and the pressure outside the chambers are balanced by virtue of the flow channels.

2. The method of claim 1, wherein the flow channels are formed by cutting.

3. The method of claim 1, wherein the flow channels are formed by etching.

4. The method of claim 1, wherein the steps of forming the flow channels comprises:
coating a photosensitive sacrificial layer on the front surface of the device wafer; and
performing a photolithography process to remove a portion of the photosensitive sacrificial layer to form the flow channels.

5. The method of claim 1, wherein the flow channels are arranged in stripes.

6. The method of claim 1, wherein the flow channels are arranged in matrix.

7. The method of claim 1, wherein the device wafer is a thin wafer.

8. The method of claim 1, further comprising performing a back surface process upon the device wafer subsequent to adhering the front surface of the device wafer to the carrier wafer.

9. The method of claim 1, wherein the front surface of the device wafer is adhered to the carrier wafer with a bonding layer.

10. The method of claim 9, wherein the bonding layer comprises photoresist, benzocyclobutene (BCB), polyimide, wax, dry film, thermal release tape or UV tape.
